(19) United States
(12) Patent Application Publication
(10) Pub. No.: US 2004/0115968 A1
(43) Pub. Date: Jun. 17, 2004

(54) Connector and printed circuit board for reducing cross-talk

(76) Inventor: Thomas S. Cohen, New Boston, NH (US)

Correspondence Address: Legal Department, Teradyne, Inc., 321 Harrison Avenue, Boston, MA, 02118, US

(21) Appl. No.: 10/320,887

(22) Filed: Dec. 17, 2002

(51) Int. Cl. H05K 1/00

(52) U.S. Cl. 439/79

(57) ABSTRACT

An interconnection system that includes a printed circuit board and an electrical connector. The printed circuit board has holes, into which contact tails from signal conductors in the connector are inserted. The connector is designed to carry differential signals so that the signal conductors are grouped in pairs. The tails of the signal conductors are offset toward each other. Further, the holes in the printed circuit boards have upper and lower portion. The upper portions align with the spacing of the contact tails of the signal conductors in the connector. The lower portions are offset from the upper portions, bringing the lower portions closer together, thereby increasing the coupling within the pair that carries one differential signal and reducing the crosstalk to adjacent pairs.

### CROSS-REFERENCES TO RELATED APPLICATIONS

Not Applicable.

### STATEMENT REGARDING FEDERALLY SPONSORED RESEARCH OR DEVELOPMENT

Not Applicable.

### REFERENCE TO MICROFICHE APPENDIX

Not Applicable

### BACKGROUND OF THE INVENTION

1. Field of the Invention This invention relates generally to interconnection systems and more particularly to board to board connections.

2. Description of Related Art

Electrical connectors are widely used in the manufacture of electronic systems because they allow the system to be built in separate pieces that can then be assembled. Board-to-board connectors are widely used because sophisticated electronic systems are usually fabricated on multiple printed circuit boards. To assemble the electronic system, the printed circuit boards are electrically connected.

In the description that follows, the invention will be illustrated as applied to a board to board connector. In particular, the invention will be illustrated in connection with a backplane-daughter card interconnection system. Many electronic systems, such as computer servers or telecommunications switches are built using a backplane and multiple “daughter” cards. In such a configuration, the active circuitry of the electronic system is built on the daughter cards. For example, a processor might be built on one daughter card. A memory bank might be built on a different daughter card. The backplane provides signal paths that route electrical signals between the daughter cards.

Generally, electrical connectors are mounted to both the backplane and the daughter card. These connectors mate to allow electrical signals to pass between the daughter card and the backplane.

Because the electronic systems that use a backplane-daughter card configuration usually process much data, there is a need for the electrical connectors to carry much data. Furthermore, this data is generally transmitted at a high data rate. There is simultaneously a need to make the systems as small as possible. As a result, there is a need to have electrical connectors that can carry many high-speed signals in a relatively small space. There is thus a need for high speed, high density connectors.

Several commercially available high-speed, high-density electrical connectors are known. For example, U.S. Pat. No. 6,299,483 to Cohen et al. entitled High Speed High Density Electrical Connector is one example. Teradyne, Inc., the assignee of that patent, sells a commercial product called VHDM®. Another example may be found in U.S. Pat. No. 6,409,543 to Astbury, et al. entitled Connector Molding Method and Shielded Waferized Connector Made Therefrom. Teradyne, Inc., the assignee of that patent, sells a commercial product called GbX™. The foregoing patents are hereby incorporated by reference.

Ideally, an interconnection system will carry signals without distortion. One type of distortion is called cross-talk. Cross-talk occurs when one signal creates an unwanted signal on another signal line. Generally, cross-talk is caused by electromagnetic coupling between signal lines. Therefore, cross-talk is a particular problem for high-speed, high-density interconnection systems. Electromagnetic coupling increases when signal lines are closer together or when the signals they carry are higher frequency. Both of these conditions are present in a high-speed, high density interconnection system. Discontinuities in the connector often exacerbate any cross-talk problems.

One approach to reducing the impact of cross-talk is to insert shielding in the connectors in the connection system. Another approach is to use differential signals. One differential signal is carried on two conductors, with the signal being represented as the difference in electrical levels between the conductors. A differential signal is more resistant to cross-talk than a single ended signal because any stray signals impinging on the conductors will generally change the levels on both conductors, but do not alter the difference in levels. Both approaches are represented in the above referenced patents.

We have recognized that further advantage in reducing cross-talk can be achieved by our inventive design for a connector and printed circuit board that changes the manner in which the connector is attached to the board.

A traditional approach to mounting components, such as connectors, to printed circuit boards is to create holes in the board. The inner walls of the holes are coated with metal or other conductive material. Inside the board, signal traces connect to the conducting wall of the holes. Conducting tails from the components are inserted into the holes, thereby forming an electrical connection between the connector and the trace inside the printed circuit board. Solder is sometimes used to make the connection, though more recently, contact tails are made with spring members that create pressure against the walls of the hole when inserted. The pressure creates a good electrical connection between the contact tail and the inner surface of the hole in what is sometimes called a press fit contact.

When the printed circuit board is thicker than the depth of the hole required to receive the contact tail, the hole is sometimes made in two steps. A small diameter hole through the board is first drilled. Then, a hole of larger diameter is drilled partially into the board from the surface centered around the small diameter hole. The contact tail fits into the larger diameter upper portion of the hole while the smaller diameter lower portion makes contact to traces in the inner layer of the printed circuit board.

The advantage of a hole with a small diameter is generally that more signal traces can be routed between the holes, allowing printed circuit boards to be made smaller. However, U.S. Pat. 6,181,219 entitled Printed Circuit Board and Method of Fabricating Such Board by Gailus, et al. describes that clearances between the smaller portion of the hole and ground planes within the printed circuit board can be adjusted to control the impedance of the hole.

### BRIEF SUMMARY OF THE INVENTION

With the foregoing background in mind, it is an object of the invention to provide a printed circuit board to which a connector can be mounted using holes that have a lower cross-talk.

To achieve the foregoing object, as well as other objectives and advantages, according to one aspect of the invention, an electrical connector is made with signal contacts that have contact tails. The contact tails are offset relative to centerline of the signal contacts. In a preferred embodiment, the signal contacts are in pairs and the offset brings the tails of the contacts in each pair of signal contacts closer together. In a preferred embodiment, each pair of signal contacts carries one differential signal.

According to another aspect of the invention, the printed circuit board has through holes for mounting components that have a larger diameter and a smaller diameter portion. The portions are not concentric. Rather, the smaller diameter holes are offset from the centerline of the large diameter holes. In a preferred embodiment, holes are created in pairs. In each pair, the smaller diameter portions of the holes are offset toward each other.

In the preferred embodiment, a connector with signal contacts with offset contact tails is mounted to the printed circuit board with holes having offset smaller diameter portions.

### BRIEF DESCRIPTION OF THE DRAWINGS

Additional objects, advantages, and novel features of the invention will become apparent from a consideration of the ensuing description and drawings, in which—

FIG. 1 is a sketch of a prior art connector;

FIG. 2 is a cross-sectional view of a portion of a backplane connector according to the invention;

FIG. 3 is a cross-sectional view of a portion of a printed circuit board; and

FIG. 4 is a cross-sectional view of a portion of a printed circuit board according to an alternative embodiment.

### DETAILED DESCRIPTION OF THE PREFERRED EMBODIMENT

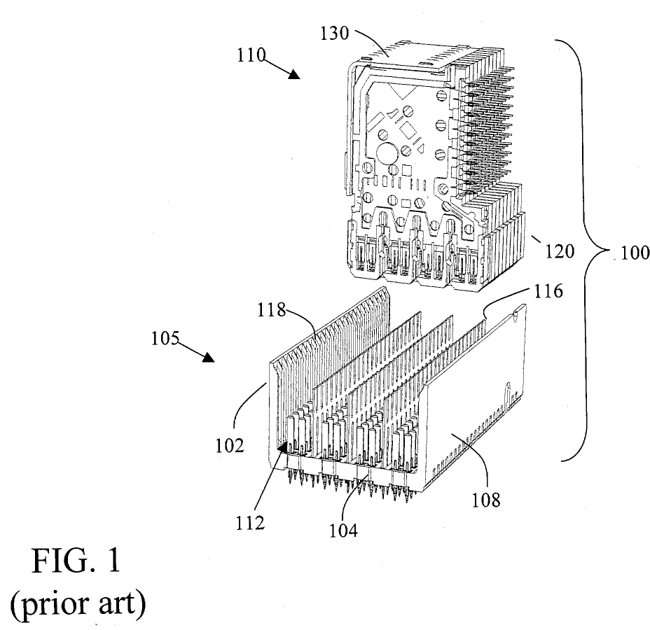

Referring to FIG. 1, a two piece electrical connector 100 is shown to include a backplane connector 105 and a daughtercard connector 110. The backplane connector 105 includes a backplane shroud 102 and a plurality of signal contacts 112, here arranged in an array of differential signal pairs. In the illustrated embodiment, the signal contacts are grouped in pairs, such as might be suitable for manufacturing a differential signal electrical connector. A single-ended configuration of the signal contacts 112 is also contemplated in which the signal conductors are evenly spaced. In the prior art embodiment illustrated, the backplane shroud 102 is molded from a dielectric material such as a liquid crystal polymer (LCP), a polyphenyline sulfide (PPS) or a high temperature nylon. All of these are suitable for use as binder materials in manufacturing connectors according to the invention.

The signal contacts 112 extend through a floor 104 of the backplane shroud 102 providing a contact area both above and below the floor 104 of the shroud 102. Here, the contact area of the signal contacts 112 above the shroud floor 104 are adapted to mate to signal contacts in daugthercard connector 110. In the illustrated embodiment, the mating contact area is in the form of a blade contact.

A tail portion of the signal contact 112 extends below the shroud floor 104 and is adapted to mating to a printed circuit board. Here, the tail portion is in the form of a press fit, “eye of the needle” compliant contact. However, other configurations are also suitable such as surface mount elements, spring contacts, solderable pins, etc. In a typical configuration, the backplane connector 105 mates with the daughtercard connector 110 at the blade contacts 106 and connects with signal traces in a backplane (not shown) through the tail portions which are pressed into plated through holes in the backplane.

The backplane shroud 102 further includes side walls 108 which extend along the length of opposing sides of the backplane shroud 102. The side walls 108 include grooves 118 which run vertically along an inner surface of the side walls 108. Grooves 118 serve to guide the daughter card connector 110 into the appropriate position in shroud 102. Running parallel with the side walls 108 are a plurality of shield plates 116, located here between rows of pairs of signal contacts 112. In a presently preferred single ended configuration, the plurality of shield plates 116 would be located between rows of signal contacts 112. However, other shielding configurations could be formed, including having the shield plates 116 running between the walls of the shrouds, transverse to the direction illustrated. In the prior art, the shield plates are stamped from a sheet of metal.

Each shield plate 116 includes one or more tail portions, which extend through the shroud base 104. As with the tails of the signal contacts, the illustrated embodiment has tail portions formed as an “eye of the needle” compliant contact which is press fit into the backplane. However, other configurations are also suitable such as surface mount elements, spring contacts, solderable pins, etc.

The daughtercard connector 110 is shown to include a plurality of modules or wafers 120 that are supported by a stiffener 130. Each wafer 120 includes features which are inserted into apertures (not numbered) in the stiffener to locate each wafer 120 with respect to another and further to prevent rotation of the wafer 120.

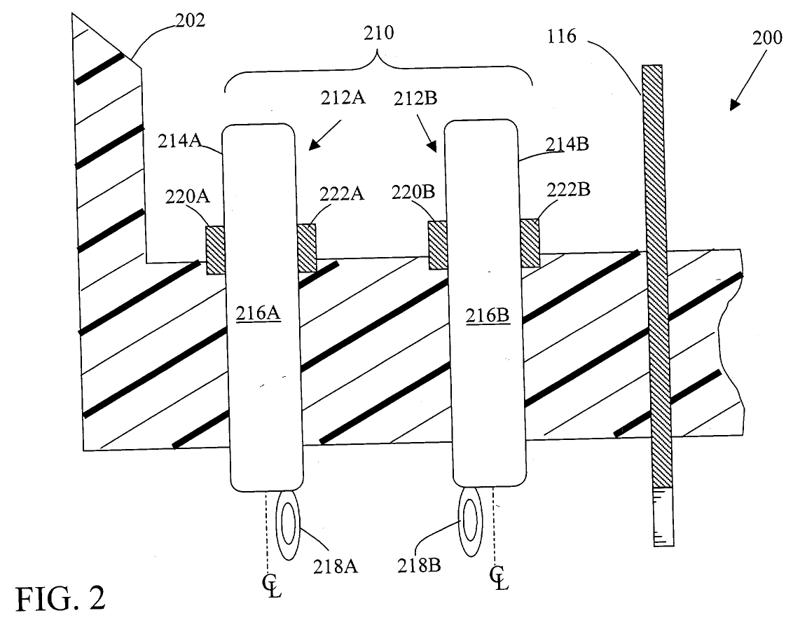

FIG. 2 shows a cross-sectional view of a portion of a backplane connector 200 adapted for use with the invention. As in the prior art, shroud 202 is made of an insulative material. Shield plates, such as shield plate 116, separate pairs of signal conductors into rows. In the view of FIG. 2, a pair 210 of signal conductors 212A and 212B are shown.

Each of the signal conductors has a mating contact portion, 214A or 214B, an intermediate portion, 216A or 216B, and a tail portion, 218A or 218B. The mating contact portions are adapted to engage another signal conductor in a mating connector. In the illustrated embodiment, the mating contact portions are blades. The signal conductor is secured to the shroud 202 at the intermediate portion. The tail is adapted to connect to a printed circuit board. In the illustrated embodiment, the tails 218A and 218B are press fit contact tails that have opposing spring beams that generate a force to secure the tail when pressed into a hole.

Unlike the prior art, contacts 212A and 212B have tails 218A and 218B that are offset from the centerline of the contacts. In the preferred embodiment, the tail of each contact in the pair is offset from the centerline in a direction toward the tail of the other contact in the pair. In the illustrated embodiment, the distance between the centerlines of the contact tails is less than the distance between the centerlines of the mating portions of the contacts. This configuration improves the performance of the interconnection system, particularly for differential signals.

The performance of a differential system is improved when each signal conductor in a pair responds exactly the same to any extraneous signal. Making the signal paths as close together as possible makes the signal conductors respond more uniformly to an extraneous signal and improves performance of the interconnection system.

In the illustrated embodiment, though the tail is offset from the centerline of the conductor, the tails 218A and 218B still fall below the intermediate sections 216A and 216B. This configuration is preferred, particularly for press fit contact tails. When the 15 contact tails are inserted into a printed circuit board, a downward force is required. Projections, such as 220A and 222A on contact 212A, provide an engagement point for a tool that can apply foce on contact 212A for insertion into a printed circuit board. The force will be transmitted through the intermediate portions 216A or 216B of the signal contacts that are secured to the housing. If the contact tail is not substantially below the intermediate portion, it is likely that there will be a weak point in the contact where the contact tail extends to the side of the intermediate portion. Thus, the contact tail is likely to buckle as it is inserted into the board. In the illustrated embodiment, contact tail 218A, though offset from the centerline of the contact, is attached to the intermediate portion 216A of the contact between the projections 220A and 222A. This mounting position reduces the chance that the contact tail will collapse upon insertion into a printed circuit board.

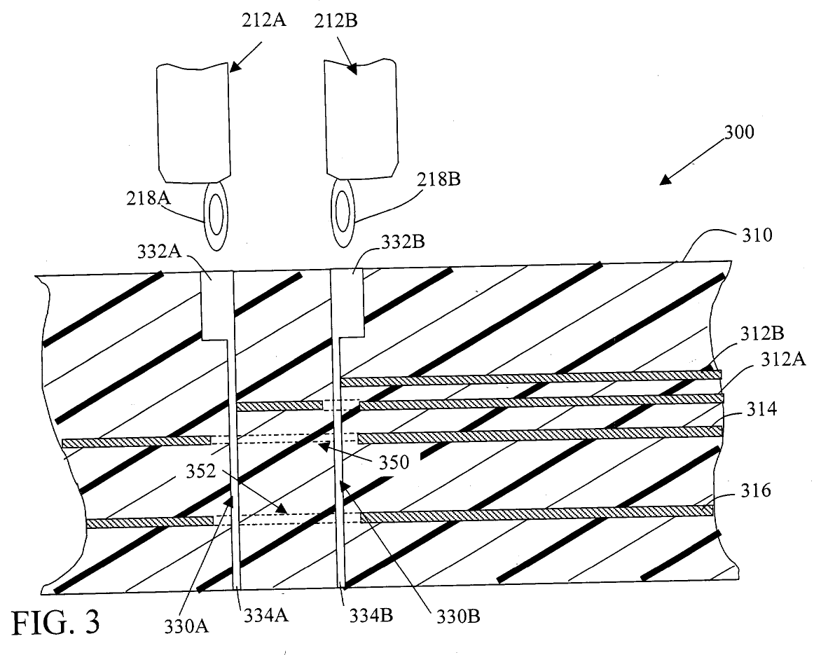

Turning now to FIG. 3, a printed circuit board 300 is shown adapted to receive a connector as in FIG. 2. In the preferred embodiment, printed circuit board 300 is made form a plurality of layers. Each layer is made from a sheet of “prepreg” material that contains a binder, such as epoxy, with conductive structures on a surface. During a traditional printed circuit board manufacturing operation, the layers are pressed together under a high temperature. This causes the binder in the separate layers to fuse, leaving a matrix of material that contains conductors in multiple planes.

In some of the planes, the conductors are in the form of traces, each of which carries a signal. In other layers, the conductors are more sheet like and are connected to power or ground when the printed circuit board is used. These layers act as grounds to the high frequency signals carried on the traces. Therefore, these layers are sometimes generally referred to as ground planes.

FIG. 3 shows printed circuit board 300 in cross section. Matrix 310 is shown as a single insulator. The layers are evident by the conductors in matrix 310. Trace 312A and 312B are on different layers. Likewise, ground planes 314 and 316 are on different layers.

The number of layers is not important to the invention. However, the hole configuration of FIG. 3 will be most useful on relatively thick boards—boards with greater than 15 layers. It will be most useful on boards having more than 20 layers or that are more than 6 mm thick. It will also be most useful with boards that carry data signals at data rates in excess of 5 Gbps.

Printed circuit board 300 includes holes to receive the contact tail of connectors or other devices to be connected to the board. Here, two holes 330A and 330B are shown to receive the contact tails of contacts 212A and 212B. However, it should be appreciated that a printed circuit board would likely have many holes, which are not shown for simplicity.

Holes 330A and 330B can be formed in the conventional way. Once the prepreg layers are fused into a board, holes are drilled through the board. A combination of electroless and electrolytic coating processes can be used to create a metal coating on the walls of the holes.

Holes 330A and 330B contain upper portions 332A and 332B. In a preferred embodiment, upper portions 332A and 332B are roughly 0.018″ (0.4 mm) in diameter and 0.075″ (1.8 mm) in depth. These holes are spaced, center to center, by 1.35 mm. Upper portions 332A and 332B are sized to receive contact tails 218A and 218B.

Holes 330A and 330B contain lower portions 334A and 334B. In the illustrated embodiment, lower portions run from the bottom of upper portions 332A and 332B to the lower surface of printed circuit board 300. Lower portions 334A and 334B connect upper portions 332A and 332B to traces, such as 312A and 312B within board 300.

As can be seen, lower portions 334A and 334B are not concentric with upper portions 332A and 332B. Rather, lower portions are offset from the centers of upper portions 332A and 332B in directions that bring them closer together. Decreasing the space between the signal conductors increases the coupling between them and decreases coupling to other signal conductors, thereby reducing crosstalk.

In the preferred embodiment, contacts 212A and 212B carry one differential signal. Thus, greater coupling between them is desirable. FIG. 3 shows that holes 330A and 330B must pass through multiple ground planes in board 300, such as ground planes 314 and 316. Ground planes 314 and 316 have openings 350 and 352 formed therein to allow the holes 330A and 330B to pass through. In the preferred embodiment, the openings 350 and 352 are each large enough to encompass both holes 330A and 330B that carries the same differential signals. Such a construction decreases crosstalk to an adjacent pair of signal conductors.

Particular advantage can be obtained when a connector of FIG. 2 is used with a printed circuit board of FIG. 3. In a preferred embodiment, the signal contacts 212A and 212B in a pair can be spaced apart by 1.85 mm. However, the holes in the printed circuit board are spaced by only 1 mm over much of their length (i.e. the lower portions). In this way, coupling between the conducting members of the pair is greatly increased, and crosstalk is correspondingly reduced.

Alternatives

Having described one embodiment, numerous alternative embodiments or variations can be made.

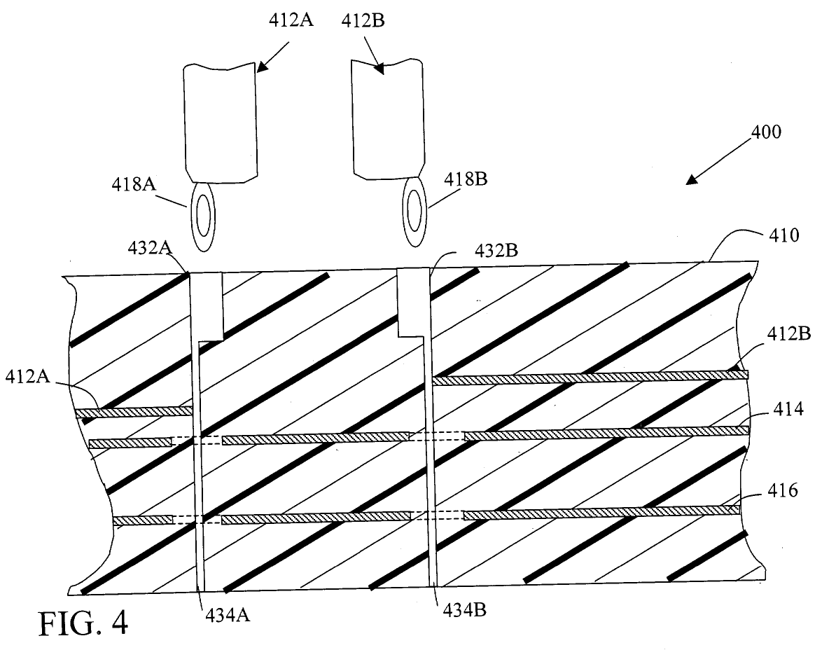

FIG. 4 shows an alternative configuration for use with single ended signals. With single ended signals, crosstalk is reduced by having adjacent signal conductors spaced further apart or by decreasing the spacing between the signal conductor and a ground.

FIG. 4 shows signal contacts 412A and 412B with the same spacing as in FIG. 3. The signal contacts have contact tails 418A and 418B that are inserted into holes 432A and 432B in a printed circuit board 410. However, in FIG. 4, the pair of signal contacts is intended to carry two single ended signals. There fore, it is desired to increase the isolation between the signal contacts.

The contact tails 418A and 418B are, as in FIG. 3, offset from the centerline of the contacts. However, unlike in FIG. 3, the contact tails are offset away from the adjacent contact. Thus, holes 432A and 432B are spaced further apart than the holes for the embodiment of FIG. 3, thereby increasing the isolation between the signal paths.

Further, the lower portions 434A and 434B are offset from the centerline of the holes 432A and 432B in opposite directions. This offset further increases the isolation between adjacent signals when the signal are single ended.

Still further embodiments might be constructed. In the case where a shield or grounded signal conductor separates adjacent signal contacts, isolation might be increased by offsetting the contact tails and the lower portions of the holes towards the ground members. Even thought the contact tails and lower hole portions are offset in the same direction for all contacts, isolation is increased by making the signal paths closer to ground paths.

As another example of an alternative, it should be realized that backplane printed circuit boards and backplane connectors were used to illustrate the invention. While the invention will be most useful with boards thicker than 20 layers, it should be appreciated that similar techniques could be employed with other types of board and other types of connectors. For example, the same constructs might be used in daughter cards or in daughter card connectors.

Lower portions 334A and 334B were illustrated as running to the lower surface of board 300. Such a configuration is the easiest to manufacture. However, it is not necessary that lower portions 334A and 334B extend beyond the traces they connect to, for example traces 312A and 312B, respectively. One way to achieve this result is to manufacture the printed circuit board 300 using a “core”. The core is a set of layers that have been fused to make what resembles a thinner printed circuit board. Then, additional layers are added to it. For example, the core might be formed of all the layers above the layer containing trace 314A. The layers below this layer would then be combined with the core to make the finished board.

The advantage of using a core is that there is less unneeded conducting material in the holes. In the embodiment of FIG. 3, the conductive coating in the holes 330 below where traces 314A and 314B connect to the holes can act like a “stub,” which creates signal reflections and distorts signals.

Alternative ways to create a circuit board without such stubs are described in High Speed Multi-Layer Printed Circuit Board VIA, by Gately, et al., U.S. patent application Ser. No. 10/007,689, which is hereby incorporated by reference.

Also, it was described that holes such as 330A and 330B are manufactured by drilling smaller diameter holes and then larger diameter holes in finished board. The order in which the holes is drilled is not important. In addition, it is possible to create holes of the desired shapes using “cores” as described above.

Further, it was described that the invention is employed in connection with the backplane portion of a board to board interconnection system. However, the invention is not limited to such applications. It might be used with other types of connectors, such as daughter card connectors, or in other areas of the interconnection system.

As an additional variation, it was described that the invention was most useful in connection with differential signals. In many interconnection systems, many different types of signals are transmitted, only some of which might be differential. Therefore, it is not necessary that all signal conductors be shaped as described to get the benefits of the invention. Benefits of the invention could be achieved by mixing signal conductors as described above with traditionally shaped signal conductors.

Further, the embodiments selected to illustrate the invention show that signal contacts with offset tails are inserted into holes that have offset lower portions. It is not necessary that both the contact tails and the lower portions of the holes be offset. Advantage could be achieved by doing either alone.

Also, the invention is not limited to use with signal contacts. For example, the benefit of offsetting a signal contact toward a ground was described. Similar benefit could be achieved by offsetting the contact tails of a ground signal toward a signal path.

Moreover, the preferred embodiment shows that the lower portions of holes 330, while not concentric with the upper portions, are nonetheless below some portion of the upper portion. Such a configuration is not strictly necessary, particularly if a “core” is used to manufacture the board. For example, the portion of board containing lower portions 334 could be manufactured as a core. Then, the portions of the board containing upper portions 332A and 332B would be added as a “cap.” Making the upper and lower portions as different pieces allows almost arbitrary relative positioning of the upper and lower portions of each hole. They could be offset from each other as shown in FIG. 3. Or, if conducting traces are built on either the upper surface of the core or the lower surface of the cap, the lower portions could be offset so far that they would not even line up below the upper portions.

While the invention has been particularly shown and described with reference to the preferred embodiments thereof, it will be understood by those skilled in the art that various changes in form and detail may be made therein without departing from the spirit and scope of the invention.

What is claimed is:

1. An interconnection system comprising:
an electrical connector having:
i) a housing;
ii) a plurality of signal conductors, each of the plurality of signal conductors having a mating portion, an intermediate portion and a contact tail;
iii) wherein each intermediate portion is attached to the housing;
iv) wherein each of the contact tails is adapted for insertion into a hole in a printed circuit board; and
v) wherein the contact tails are offset to provide a different spacing between contact tails of the signal conductors of adjacent signal conductors than between the mating contact portions of the signal conductors of those signal conductors.

2. The interconnection system of claim 1 wherein the contact tails comprise press fit contacts.

3. The interconnection system of claim 1 wherein the mating contact portions comprise blade contacts.

4. The interconnection system of claim 3 wherein the contact tails comprise press fit contacts.

5. The interconnection system of claim 1 wherein for each signal contact the intermediate portions of each signal conductor has a centerline and each contact tail has a centerline and the centerline of each contact tail is below the intermediate portion but offset from the centerline of the intermediate portion.

6. The interconnection system of claim 1 wherein the electrical connector comprises a backplane connector having a plurality of shield members running the length of the connector and the plurality of pairs of signal conductors are arranged in rows parallel to the shield members.

7. The interconnection system of claim 6 wherein for each signal contact the intermediate portions of each signal conductor has a centerline and each contact tail has a centerline and the centerline of each contact tail is offset from the centerline of the intermediate portion in a direction perpendicular to the shield members.

8. The interconnection system of claim 7 wherein the mating contact portion is a blade and the contact tail is a press fit contact.

9. The interconnection system of claim 1 wherein the signal conductors are organized in pairs and the contact tails of the signal conductor of a pair are offset towards each other.

10. The interconnection system of claim 1 wherein the contact tails of a signal conductor and an adjacent signal conductor are offset away from each other.

11. The interconnection system of claim 1 additionally comprising a printed circuit board, the board having a plurality of holes with the contact tails of the plurality of signal conductors inserted into the holes.

12. The interconnection system of claim 11 wherein each of the holes has an upper portion having a first diameter and a lower portion having a second diameter and the first diameter is larger than the second diameter.

13. The interconnection system of claim 11 wherein, for each of the holes, the centerline of the lower portion is offset from the centerline of the upper portion.

14. The interconnection system of claim 13 wherein the plurality of holes are grouped in pairs corresponding to the pairs of signal conductors and, lower portions of the holes in each pair are offset toward each other.

15. The interconnection system of claim 14 wherein the printed circuit board comprises at least 20 layers.

16. The interconnection system of claim 14 wherein:
i) the printed circuit board comprises a plurality of ground planes;
ii) the plurality of ground planes have openings therethrough; and
iii) each of the pair of holes passes through the same hole.

17. The interconnection system of claim 1 wherein:
a) each signal conductor has opposing sides with tabs adapted to engage an insertion tool extending therefrom; and
b) the contact tails are disposed between the tabs.

18. An interconnection system comprising:
a printed circuit board, having:
i) a plurality of holes formed therein, each of the holes having conductive inner walls;
ii) wherein each of the holes has an upper portion having a first diameter and a lower portion having a second diameter smaller than the first diameter;
iii) a plurality of conductive traces within the printed circuit board;
iv) wherein each of the conductive traces is connected to the lower portion of one of the holes; and
v) wherein the lower portions of the holes are offset from the center line of the upper portion of the hole.

19. The interconnection system of claim 18 wherein the lower portion of each hole is below, but not concentric with, the upper portion of each hole.

20. The interconnection system of claim 18 wherein the lower portion of each hole have a smaller diameter than the upper portion.

21. The interconnection system of claim 18 wherein the lower portions of each hole in a pair are spaced by a distance of less than 1.2 mm.

22. The interconnection system of claim 21 wherein the upper portions of adjacent holes are spaced by a distance of greater than 1.2 mm.

23. The interconnection system of claim 18 wherein the holes are organized in pairs with the lower portions of the holes in each pair offset towards each other and the printed circuit board further comprises a plurality of ground planes and the ground planes have openings therethrough, with the lower portions of only one pair of holes passing through each opening.

24. The interconnection system of claim 18 wherein the holes are organized in pairs with the lower portions of each hole in a pair offset toward each other and each pair of holes carries a differential signal.
